(19) United States
(12) Patent Application Publication
(10) Pub. No.: US 2026/0190250 A1
(43) Pub. Date: Jul. 2, 2026

(54) DISPLAY DEVICE

(71) Applicant: Guangzhou China Star Optoelectronics Semiconductor Display Technology Co., Ltd., Guangzhou (CN)

(72) Inventors: Jun WANG, Guangzhou (CN); Junjie LI, Guangzhou (CN); Lei LIU, Guangzhou (CN); Feng LIU, Guangzhou (CN)

(73) Assignee: Guangzhou China Star Optoelectronics Semiconductor Display Technology Co., Ltd., Guangzhou (CN)

(21) Appl. No.: 19/240,108

(22) Filed: Jun. 17, 2025

(30) Foreign Application Priority Data
Dec. 31, 2024 (CN) 202411997217.4

(51) Int. Cl. H05K 5/02

(52) U.S. Cl. CPC H05K 5/0217

(57) ABSTRACT

A display device is provided. The display device includes a support frame, a display panel, a magnetic member and a decorative member. The display panel is fixed to the support frame, the magnetic member is fixed to the support frame, and the decorative member is adsorbed to the magnetic member.

### CROSS-REFERENCE TO RELATED APPLICATION

This application claims priority to and the benefit of Chinese Patent Application No. 202411997217.4, filed on Dec. 31, 2024, the disclosure of which is incorporated herein by reference in its entirety.

### TECHNICAL FIELD

The present application relates to the field of display technology, and in particular, to a display device.

### BACKGROUND

Display devices have been widely used in various electronic products as display components of electronic devices. The conventional display device is inconvenient to disassemble and assemble, especially for the display device having the display module. When the display module needs to be replaced or maintained, the disassembly and assembly of the display device takes a long time and the efficiency is low.

### SUMMARY

Embodiments of the present disclosure provide a display device, which facilitates disassembly and replacement of the decorative member, so as to at least partially solve the technical problem described above.

In order to achieve the object described above, the embodiments of the present disclosure provide a display device. The display device includes a support frame, a display panel, a magnetic member and a decorative member. The display panel is fixed to the support frame. The magnetic member is fixed to the support frame. The decorative member is adsorbed to the magnetic member.

Optionally, the support frame includes one or more support protruding portions, the one or more support protruding portions protrude toward the decorative member, and the magnetic member is fixed to the one or more support protruding portions.

Optionally, the support protruding portions are spaced apart, the display device further includes a plurality of flexible films, one end of each of the plurality of flexible films is bonded to the display panel, and each of the plurality of flexible films is disposed between adjacent ones of the support protruding portions.

Optionally, the support frame further includes a frame body, the one or more support protruding portions are located on the frame body, and the display panel is fixed to the frame body.

Optionally, the display panel further includes an array substrate, the array substrate includes a pin bonding area, a portion of the magnetic member is further fixed to a portion of the array substrate corresponding to the pin bonding area, and the decorative member shields the pin bonding area.

Optionally, a gap is provided between the pin bonding area and the one or more support protruding portions.

Optionally, the display panel further includes an opposite substrate, the opposite substrate is disposed opposite to the array substrate, the pin bonding area is extended outwardly relative to the opposite substrate, and a thickness of the magnetic member is less than or equal to a thickness of the opposite substrate.

Optionally, the display device further includes an adhesive layer, and the adhesive layer adheres the magnetic member and the support frame.

Optionally, the display device further includes a first polarizer, and the first polarizer is attached to a surface of the display panel facing away from the support frame; wherein the decorative member is further attached to the surface of the display panel facing away from the support frame and is adjacent to the first polarizer.

Optionally, the display device further includes a coating layer, the coating layer is disposed on a surface of the decorative member facing away from the magnetic member, and a color of the coating layer is same as a color of a surface of the first polarizer facing away from the display panel.

Optionally, a sum of a thickness of the coating layer and a thickness of the decorative member is equal to a thickness of the first polarizer.

In the display device according to the embodiments of the present disclosure, the decorative member is fixed to the display device by using the magnetic adsorption force of the magnetic member, which not only simplifies the installation process of the decorative member, but also facilitates the disassembly and replacement of the decorative member.

### BRIEF DESCRIPTION OF THE DRAWINGS

FIG. 1 is a schematic diagram of an exploded structure of a display device according to some embodiments of the present disclosure;

FIG. 2 is a schematic diagram of an exploded structure of a support frame and a magnetic member according to some embodiments of the present disclosure;

FIG. 3 is a schematic diagram of another exploded structure of a support frame and a magnetic member according to some embodiments of the present disclosure;

FIG. 4 is a schematic diagram of a cross-sectional structure of a display device according to some embodiments of the present disclosure;

FIG. 5 is a schematic diagram of another cross-sectional structure of a display device according to some embodiments of the present disclosure.

The reference numerals are listed below:
100. Display device;
11. Display panel;
12. Array substrate; 12A. Array area; 12B. Pin bonding area; 121. Base;
13. Opposite substrate; 131. Opposite base;
14. Backlight module; 141. Optical film; 142. Light source; 143. Backplane; 144. Light-transmitting plate;
21. Support frame; 211. Frame body; 212. Support protruding portion; 212A. Support plane;

31. Magnetic member;

41. Decorative member; 411. Flat portion; 412. First bending portion;

51. Fixing member; 511. Adhesive layer;

61. Flexible film; 62. Driving unit;

711. First polarizer; 712. Second polarizer;

81. Coating layer; 82. Protective film;

91. Middle frame; 911. Middle frame body; 912. Installation portion.

### DETAILED DESCRIPTION

The technical solutions in the embodiments of the present disclosure will be clearly and completely described below in conjunction with the accompanying drawings in the embodiments of the present disclosure. It is apparent that the embodiments described herein are only some of the embodiments of the present disclosure, but not all of the embodiments of the present disclosure. Based on the embodiments of the present disclosure, all other embodiments obtained by those skilled in the art without making creative efforts fall within the scope of protection of the present disclosure.

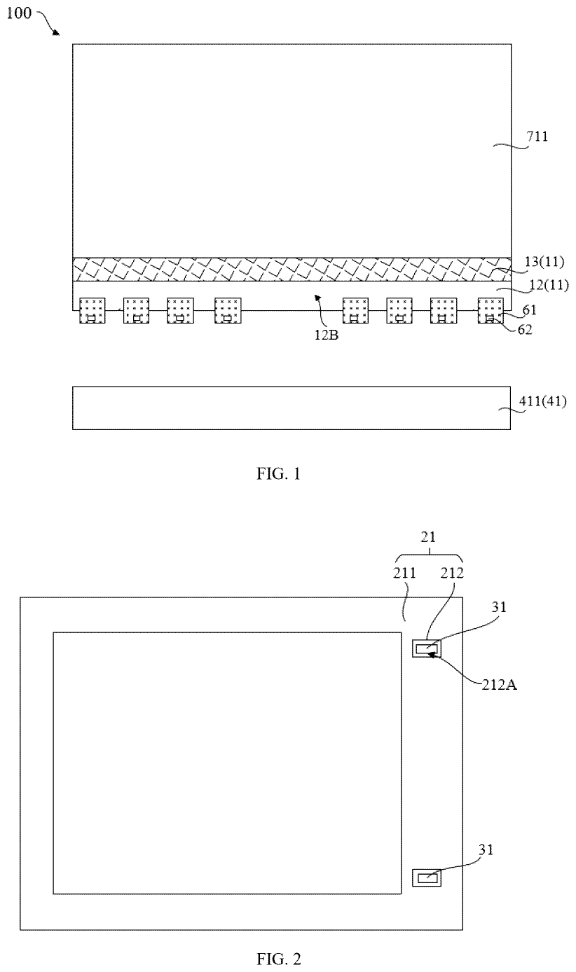

Refer to FIG. 1 to FIG. 5, the display device 100 includes a display panel 11. The display panel 11 is configured for display. The display panel 11 can be any one of the following: a liquid crystal display panel, an organic light-emitting diode display panel, a quantum dot display panel, a micro light-emitting diode display panel, or a sub-millimeter light-emitting diode display panel. The display panel 11 can be any one of a flexible display panel, a foldable display panel, a rollable display panel, and a rigid display panel.

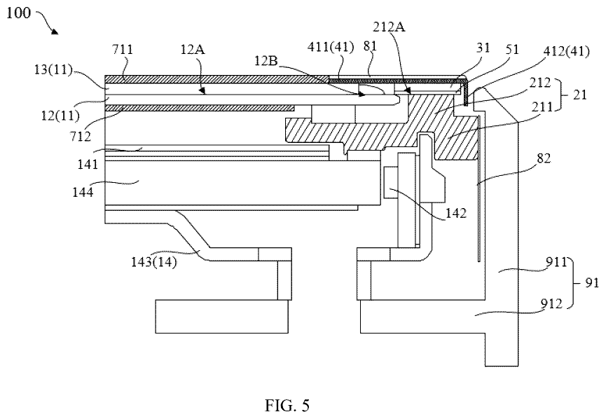

In some embodiments, referring to FIG. 1, FIG. 4, and FIG. 5, the display panel 11 includes an array substrate 12. The array substrate 12 includes an array area 12A and a pin bonding area 12B. The array area 12A is adjacent to the pin bonding area 12B.

The array area 12A of the array substrate 12 overlaps with the display area of the display panel 11. The array substrate 12 includes a base. The array area 12A is provided with a pixel driving circuit (not shown) and a signal line (not shown) disposed on the base, and the signal line is connected to the pixel driving circuit.

The pin bonding area 12B of the array substrate 12 overlaps with the non-display area of the display panel 11. The pin bonding area 12B is provided with a plurality of bonding pins (not shown) disposed on the base, and the plurality of bonding pins are connected to a plurality of signal lines (not shown) in the array area 12A. The bonding pin is configured to input a driving signal and output the driving signal to the pixel driving circuit through the signal line, so that the display panel 11 realizes display.

In some embodiments, referring to FIG. 1, FIG. 4, and FIG. 5, the display panel 11 further includes an opposite substrate 13. The opposite substrate 13 is disposed opposite to the array substrate 12. The pin bonding area 12B is extended outwardly relative to the opposite substrate 13 to facilitate bonding of the flexible film 61 carrying the driving unit 62 to the bonding pins in the pin bonding area 12B.

In some embodiments, the opposite substrate 13 and the array substrate 12 can be connected by a frame adhesive (not shown).

In some embodiments, a liquid crystal layer (not shown in the figure) is disposed between the opposite substrate 13 and the array substrate 12. In other words, the display panel 11 is a liquid crystal display panel.

In some embodiments, the opposite substrate 13 can include an opposite base 131 and a color film layer (not shown in the figure), and the color film layer is located on the side of the opposite base 131 facing the array substrate 12, that is, the opposite substrate 13 is a color film substrate. In some other embodiments, the opposite substrate 13 may also be an encapsulation substrate.

In some embodiments, referring to FIG. 2 to FIG. 5, the display device 100 further includes a support frame 21. The support frame 21 serves to support and fix the display panel 11. The support frame 21 is in a frame-like shape. The material of the support frame 21 may include a rigid plastic such as polycarbonate, allowing the support frame 21 to have a sufficient mechanical strength while also reducing its mass.

In some embodiments, the support frame 21 includes a frame body 211. The frame body 211 is in a frame-like shape, and an opening is provided in the middle of the frame body 211. The display panel 11 is fixed to the frame body 211. In an exemplary embodiment, referring to FIG. 4 and FIG. 5, in a case where the display panel 11 includes the array substrate 12, the side of the array substrate 12 facing away from the opposite substrate 13 is fixed to the frame body 211 by an adhesive layer. The adhesive layer may include, but is not limited to, foam adhesive and the like.

In some embodiments, referring to FIG. 4 and FIG. 5, when the display panel 11 is a liquid crystal display panel 11, the display device 100 further includes a backlight module 14. The backlight module 14 may include a light-transmitting plate 144, such as a light guiding plate, and the light-transmitting plate 144 is fixed to the side of the support frame 21 facing away from the display panel 11.

In some embodiments, referring to FIG. 4 and FIG. 5, the backlight module 14 may further include an optical film 141. The optical film 141 is disposed on the light-transmitting plate 144. The optical film 141 may include at least one of a brightness enhancement film and a diffusion film.

In some embodiments, referring to FIG. 4 and FIG. 5, the backlight module 14 may further include a light source 142. The light source 142 may be located on the side surface of the light-transmitting plate 144. The light source 142 may be located on the side of the light-transmitting plate 144 away from the display panel 11.

In some embodiments, referring to FIG. 4 and FIG. 5, the backlight module 14 may further include a backplane 143. The backplane 143 includes an accommodating space in which the light source 142, the light-transmitting plate 144, the optical film 141, and the like are disposed. The support frame 21 is fixed to the backplane 143 to realize the fixation of the support frame 21.

In some embodiments, referring to FIG. 1 to FIG. 5, the display device 100 further includes a magnetic member 31 and a decorative member 41. The decorative member 41 plays a decorative role on the display device 100 and beautifies the appearance of the display device 100. The magnetic member 31 is fixed to the support frame 21. The decorative member 41 is adsorbed to the magnetic member 31. The decorative member 41 is fixed to the display device 100 by using the magnetic adsorption force of the magnetic member 31, which not only simplifies the installation process of the decorative member 41, but also facilitates the disassembly and replacement of the decorative member 41.

In some embodiments, the magnetic member 31 may include, but is not limited to, a magnetic material such as a neodymium iron boron magnet.

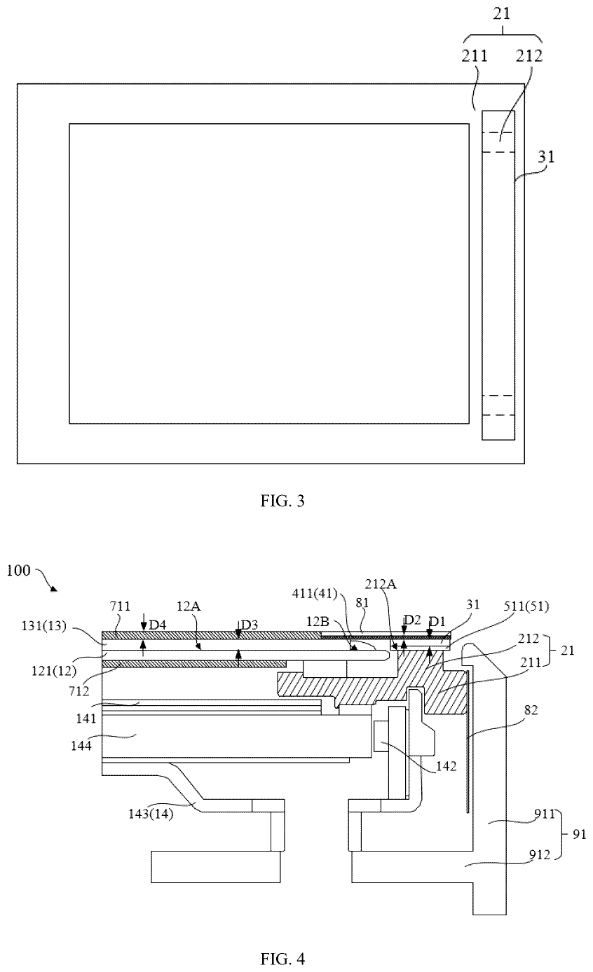

In some embodiments, referring to FIG. 2 and FIG. 3, one or more magnetic members 31 are fixed to the support frame 21. Referring to FIG. 2, when the decorative member 41 is fixed to the support frame 21 by a plurality of magnetic members 31, the risk of damage to the plurality of magnetic members 31 during molding and usage is smaller. Referring to FIG. 3, when the decorative member 41 is fixed to the support frame 21 by one magnetic member 31, the installation of the magnetic member 31 is simpler.

In some embodiments, referring to FIG. 2 to FIG. 5, the magnetic member 31 is in a sheet-like shape, thereby simplifying the formation process of the magnetic member.

In some embodiments, the thickness D1 of the magnetic member 31 may be greater than the thickness D2 of the decorative member 41, thereby reducing the risk of damage to the magnetic member 31 during molding and usage due to being too thin.

In some embodiments, the thickness D1 of the magnetic member 31 may be greater than or equal to the thickness D3 of the opposite substrate 13, thereby reducing the risk of damage to the magnetic member 31 during molding and usage due to being too thin.

In some other embodiments, the thickness D1 of the magnetic member 31 may be less than the thickness D3 of the opposite substrate 13, reducing the risk that the magnetic member 31 protrudes from the opposite substrate 13, thereby reducing the risk that a significant gap difference is formed between the decorative member 41 located on the magnetic member 31 and the display panel 11, and improving the appearance effect of the display device 100.

In some embodiments, the thickness D1 of the magnetic member 31 may be greater than or equal to 0.15 millimeters and less than or equal to 0.5 millimeters, thereby reducing the risk of damage to the magnetic member 31 during molding and usage due to being too thin, while reducing the risk of the gap difference of the decorative member 41 due to the magnetic member 31 being too thick.

Optionally, the thickness D1 of the magnetic member 31 may be greater than or equal to 0.2 millimeters and less than or equal to 0.4 millimeters. Optionally, the thickness of the magnetic member 31 can be greater than or equal to 0.25 millimeters and less than or equal to 0.4 millimeters.

In some embodiments, referring to FIG. 2 to FIG. 5, the support frame 21 further includes one or more support protruding portions 212, and the support protruding portions 212 are located on the frame body 211. The support protruding portion 212 protrudes toward the decorative member 41, and the magnetic member 31 is fixed to the support protruding portion 212. The design of the support protruding portion 212 not only reduces the risk of mutual interference between the magnetic member 31 and the display panel 11 when the magnetic member 31 and the display panel 11 are both installed on the support frame 21, but also plays a role in raising the magnetic member 31 and the decorative member 41.

In some embodiments, the support protruding portion 212 may be integrally formed with the frame body 211. Exemplarily, the support protruding portion 212 and the frame body 211 may include the same hard material, for example, hard plastic or metal, so as to ensure that the support protruding portion 212 has good mechanical strength.

In some other embodiments, the support protruding portion 212 may also be connected to the frame body 211 through a connecting member. The connecting member may include an adhesive layer and the like.

In still other embodiments, the support protruding portion 212 may include a hard adhesive layer, so that the support protruding portion 212 not only provides a support function, but also plays a role of adhering the magnetic member 31.

In some embodiments, referring to FIG. 4 and FIG. 5, the support protruding portion 212 may include a support plane 212A, and the support plane 212A faces the decorative member 41. The magnetic member 31 is fixed to the support plane 212A.

In some embodiments, as shown in FIG. 2, the area of the support plane 212A may be greater than the area of the magnetic member 31 toward the support protruding portion 212, so that the support plane 212A provides a larger support area for the magnetic member 31, thereby reducing the risk of damage to the magnetic member 31.

In some embodiments, referring to FIG. 3, the area of the magnetic member 31 toward the support protruding portion 212 is greater than the sum of the areas of the support planes 212A of the plurality of support protruding portions 212.

In some embodiments, referring to FIG. 4 and FIG. 5, in a case where the surface of the support protruding portion 212 facing the decorative member 41 includes the support plane 212A, the support plane 212A may be adjacent to the surface of the array substrate 12 located in the pin bonding area 12B. In this way, it facilitates the fixation of the magnetic member 31 both to the array substrate 12 and the support frame 21, so that the magnetic member 31 is more stably fixed, thereby improving the installation reliability of the fixation of the decorative member 41 to the magnetic member 31.

In some embodiments, referring to FIG. 4 and FIG. 5, a gap is provided between the pin bonding area 12B and the support protruding portion 212, which reduces the risk of installation interference between the support protruding portion 212 and the pin bonding area 12B of the array substrate 12.

In some embodiments, referring to FIG. 4 to FIG. 5, the display device 100 further includes a fixing member 51. The magnetic member 31 is fixed to the support frame 21 through the fixing member 51.

In some embodiments, the fixing member 51 includes an adhesive layer 511. The adhesive layer 511 adheres the magnetic member 31 and the support frame 21, so as to fix the magnetic member 31 to the support frame 21. In an exemplary embodiment, the adhesive layer 511 adheres the support protruding portion 212 and the magnetic member 31.

In some embodiments, referring to FIG. 3 and FIG. 4, the adhesive layer 511 may be located on the support plane 212A of the support protruding portion 212. The support plane 212A faces the decorative member 41. In this way, the process of fixing the adhesive layer 511 to the support protruding portion 212 is simplified.

In some other embodiments, the adhesive layer 511 may be located on the supporting plane 212A and the side surface of the support protruding portion 212. The support plane 212A of the support protruding portion 212 faces the decorative member 41. The side surface of the support protruding portion 212 is connected to the support plane 212A of the support protruding portion 212. In this way, the contact area between the adhesive layer 511 and the support protruding portion 212 is increased.

In some embodiments, the thickness of the adhesive layer 511 is less than the thickness D1 of the magnetic member 31, by ensuring that the thickness D1 of the magnetic member 31 is greater than the thickness of the adhesive layer 511, the risk of damage to the magnetic member 31 during molding and usage due to being too thin can reduced.

In some embodiments, the absolute value of the difference between the sum of the thickness of the adhesive layer 511 and the thickness of the magnetic member 31 and the thickness of the opposite substrate 13 is less than 0.2 millimeters, thereby reducing the risk that the magnetic member 31 protrudes from the opposite substrate 13, and further reducing the risk of forming a gap difference between the decorative member 41 located on the magnetic member 31 and the display panel 11,

In some other embodiments, the fixing member 51 may be an accommodating groove (not shown in the figure) disposed on the support frame 21. In one exemplary embodiment, the support plane 212A of the support protruding portion 212 may be provided with the accommodating groove. The accommodating groove is disposed toward the decorative member 41. The magnetic member 31 is fixed in the accommodating groove, and the accommodating groove plays a role of installing and limiting the magnetic member 31, thereby reducing the risk of movement of the magnetic member 31, and further reducing the risk of movement of the decorative member 41.

In still other embodiments, the fixing member 51 may further include a magnet member (not shown in the figure). The magnetic member 31 is fixed to the support frame 21 by the magnet member. The magnet member can be embedded in the groove of the support frame 21.

In some embodiments, referring to FIG. 5, while the magnetic member 31 is fixed to the support frame 21, the magnetic member 31 is further fixed to a portion of the array substrate 12 corresponding to the pin bonding area 12B, and the decorative member 41 shields the pin bonding area 12B. The magnetic member 31 is fixed to the pin bonding area 12B of the array substrate 12, thereby improving the stability of the fixation of the magnetic member 31. Further, the decorative member 41 serves to shield the pin bonding area 12 B to beautify the appearance of the display device 100.

In some embodiments, as shown in FIG. 2 and FIG. 3, the plurality of support protruding portions 212 are spaced apart. The display device 100 further includes a plurality of flexible films 61. One end of the flexible film 61 is bonded to the display panel 11, and the flexible film 61 is disposed between adjacent support protruding portions 212. A gap is provided between the plurality of supporting protruding portions 212 to provide an accommodation space for the flexible film 61, thereby reducing the risk of damage to the flexible film 61. One end of the flexible film 61 is bonded to the bonding pin of the pin bonding area 12B.

In some embodiments, a gap is provided between the flexible film 61 and the side surface of the support protruding portion 212, thereby reducing the risk of damage to the flexible film 61 by the support protruding portion 212. The side surface of the support protruding portion 212 is connected to the support plane 212A of the support protruding portion 212 facing the decorative member 41.

In some embodiments, referring to FIG. 1, a driving chip 62 is disposed on the flexible film 61. The driving chip 62 outputs a driving signal to the bonding pin through the line on the flexible film 61. Exemplarily, the other end of the flexible film 61 is bent to the backside of the backlight module 14, and the driving chip 62 is disposed on the backside of the backlight module 14. The other end of the flexible film 61 is opposite to the end of the flexible film 61 bonded to the display panel.

In some embodiments, referring to FIG. 4 and FIG. 5, the display device 100 further includes a protective film 82, and the protective film 82 is fixed to the support frame 21. The protective film 82 is located on the side of the flexible film 61 away from the opening of the support frame 21.

In some embodiments, referring to FIG. 1, FIG. 4 and FIG. 5, the display device 100 further includes a first polarizer 711. The first polarizer 711 is attached to the surface of the display panel 11 away from the support frame 21. The first polarizer 711 is configured to adjust the display effect of the display device 100.

In some embodiments, referring to FIG. 4 and FIG. 5, the display device 100 further includes a second polarizer 712. The display panel 11 is located between the first polarizer 711 and the second polarizer 712. The first polarizer 711 cooperates with the second polarizer 712 to adjust the display effect of the display device 100.

In some embodiments, the material of the decorative member 41 may include a metal such as stainless steel, so that the decorative member 41 not only plays a decorative role, but also has a certain mechanical strength to reduce the risk of damage under the action of external force.

In some embodiments, referring to FIG. 4 and FIG. 5, the decorative member 41 is further attached to the surface of the display panel 11 facing away from the support frame 21 and is adjacent to the first polarizer 711. In this way, no gap difference is provided between the decorative member 41 and the surface of the display panel 11 on which the first polarizer 711 is disposed, so as to improve the appearance effect of the display device 100. Further, the decorative member 41 is adjacent to the first polarizer 711, so as to reduce or even eliminate the gap between the decorative member 41 and the first polarizer 711, thereby further improving the appearance effect of the display device 100.

In an exemplary embodiment, referring to FIG. 4 and FIG. 5, the first polarizer 711 and the decorative member 41 are spliced so that there is no gap between the first polarizer 711 and the decorative member 41, thereby improving the appearance effect of the display device 100.

In some embodiments, the thickness D2 of the decorative member 41 is less than or equal to the thickness D4 of the first polarizer 711, thereby reducing the risk that the decorative member 41 protrudes from the first polarizer 711, and improving the appearance effect of the display device 100.

In some embodiments, the display device 100 further includes a coating layer 81. The coating layer 81 is located on the surface of the decorative member 41 facing away from the magnetic member 31, and the color of the coating layer 81 is the same as the color of the surface of the first polarizer 711 facing away from the display panel 11. The appearance of the coating layer 81 tends to be the same as the appearance of the first polarizer 711, so that the display panel 11 can achieve a frameless effect.

In some embodiments, the coating layer 81 may be formed by at least one of an ink printing process and a painting process.

In some embodiments, the sum of the thickness of the coating layer 81 and the thickness D2 of the decorative member 41 is equal to the thickness D4 of the first polarizer 711. It is ensured that there is no gap difference between the coating layer 81 and the first polarizer 711 to achieve a better product appearance effect.

In some implementations, the thickness D2 of the decorative member 41 is greater than the thickness of the coating layer 81. It is ensured that the decorative member 41 has a relatively large thickness D2, so that the decorative member has sufficient mechanical strength to play a protective role.

In some embodiments, referring to FIG. 1, FIG. 4, and FIG. 5, the decorative member 41 may include a flat portion 411, and the flat portion 411 is in a strip-like shape. The flat portion 411 is fixed to the support frame 21, then passes above the pin bonding area 12B of the array substrate 12, and finally extends to be spliced with the first polarizer 711. In this way, the decorative member 41 can be used to replace the front frame in the related art, so as to play a role in shielding the pin bonding area 12B of the array substrate 12, and further eliminate the gap difference between the pin bonding area 12B and the display panel 11.

In some other embodiments, referring to FIG. 5, the decorative member 41 may further include a first bending portion 412. The first bending portion 412 is bent toward the support frame 21 with respect to the flat portion 411. When the decorative member 41 is moved until the first bending portion 412 comes into contact with the support protruding portion 212, the decorative member 41 can be restricted from further significant displacement.

In some other embodiments, continuing referring to FIG. 5, in a case where the support frame 21 includes the support protruding portion 212, a gap is provided between the first bending portion 412 and the support protruding portion 212. It is ensured that there is more movement space for the splicing of the decorative member 41 and the first polarizer 711, thereby reducing the installation difficulty of the decorative member 41.

In some other embodiments, the display device 100 further includes a middle frame 91. The middle frame 91 includes a middle frame body 911. The middle frame body 911 is disposed around the support frame 21. In a case where the decorative member 41 further includes the first bending portion 412 and the support frame 21 includes the support protruding portion 212, the first bending portion 412 is located between the middle frame body 911 and the support protruding portion 212, and a gap is also provided between the first bending portion 412 and the middle frame body 911. When the decorative member 41 is moved until the first bending portion 412 comes into contact with the middle frame body 911, the decorative member 41 can be restricted from further significant displacement.

In still other embodiments, the decorative member 41 may further include a second bending portion (not shown in the figure), and the second bending portion is connected to the first bending portion 412.

Referring to FIG. 3 and FIG. 4, in a case where the display device 100 further includes the backlight module 14, the middle frame body 911 is further disposed around the backlight module 14. The middle frame 91 provides protection for the display panel 11 and the backlight module 14.

In some other embodiments, the middle frame 91 further includes an installation portion 912. The installation portion 912 is connected to the middle frame body 911. The installation portion 912 is detachably connected to the backplane 143 of the backlight module 14.

To sum up, in the display device according to the embodiments of the present disclosure, the decorative member is fixed to the display device by using the magnetic adsorption force of the magnetic member, which not only simplifies the installation process of the decorative member, but also facilitates the disassembly and replacement of the decorative member.

The description of the above embodiments is merely provided to help understand the technical solution and the core idea of the present disclosure. It should be understood that, a person skilled in the art may modify the technical solutions recorded in the foregoing embodiments, or to equivalently replace some of the technical features. However, these modifications or replacements do not cause the essence of the corresponding technical solution to depart from the scope of the technical solution of each embodiment of the present disclosure.

What is claimed is:

1. A display device comprising:
a support frame;
a display panel fixed to the support frame;
a magnetic member fixed to the support frame; and
a decorative member adsorbed to the magnetic member.

2. The display device according to claim 1, wherein the support frame comprises one or more support protruding portions, the one or more support protruding portions protrude toward the decorative member, and the magnetic member is fixed to the one or more support protruding portions.

3. The display device according to claim 2, wherein the support protruding portions are spaced apart, the display device further comprises a plurality of flexible films, one end of each of the plurality of flexible films is bonded to the display panel, and each of the plurality of flexible films is disposed between adjacent ones of the support protruding portions.

4. The display device according to claim 3, wherein the display device further comprises a protective film, the protective film is fixed to the support frame, and the protective film is located on a side of the plurality of flexible films facing away from an opening of the support frame.

5. The display device according to claim 2, wherein the support frame further comprises a frame body, the one or more support protruding portions are located on the frame body, and the display panel is fixed to the frame body.

6. The display device according to claim 2, wherein the display panel further comprises an array substrate, the array substrate comprises a pin bonding area, a portion of the magnetic member is further fixed to a portion of the array substrate corresponding to the pin bonding area, and the decorative member shields the pin bonding area.

7. The display device according to claim 6, wherein a gap is provided between the pin bonding area and the one or more support protruding portions.

8. The display device according to claim 6, wherein the display panel further comprises an opposite substrate, the opposite substrate is disposed opposite to the array substrate, the pin bonding area is extended outwardly relative to the opposite substrate, and a thickness of the magnetic member is less than or equal to a thickness of the opposite substrate.

9. The display device according to claim 2, wherein each of the one or more support protruding portions comprises a support plane, the support plane faces the decorative member, and the magnetic member is fixed to the support plane.

10. The display device according to claim 9, wherein an area of the support plane is greater than an area of the magnetic member toward the one or more support protruding portions.

11. The display device according to claim 9, wherein an area of the magnetic member toward the support protruding portions is greater than a sum of areas of support planes of the support protruding portions.

12. The display device according to claim 2, wherein the decorative member comprises a flat portion and a first bending portion, and the first bending portion is bent toward the support frame with respect to the flat portion.

13. The display device according to claim 12, wherein a gap is provided between the first bending portion and the one or more support protruding portions.

14. The display device according to claim 1, wherein the display device further comprises a fixing member, and the magnetic member is fixed to the support frame by the fixing member.

15. The display device according to claim 14, wherein the fixing member comprises an adhesive layer, and the adhesive layer adheres the magnetic member and the support frame.

16. The display device according to claim 1, further comprising:
a first polarizer attached to a surface of the display panel away from the support frame;
wherein the decorative member is further attached to the surface of the display panel away from the support frame and is adjacent to the first polarizer.

17. The display device according to claim 16, further comprising:
a coating layer disposed on a surface of the decorative member facing away from the magnetic member, and a color of the coating layer is same as a color of a surface of the first polarizer facing away from the display panel.

18. The display device according to claim 17, wherein a sum of a thickness of the coating layer and a thickness of the decorative member is equal to a thickness of the first polarizer.

19. The display device according to claim 1, wherein the magnetic member comprises a plurality of magnetic members, and the decorative member is fixed to the support frame by the plurality of magnetic members.

20. The display device according to claim 1, wherein a thickness of the magnetic member is greater than a thickness of the decorative member.
